(19) United States
(12) Patent Application Publication
(10) Pub. No.: US 2026/0107666 A1
(43) Pub. Date: Apr. 16, 2026

(54) DISPLAY DEVICE AND ELECTRONIC DEVICE INCLUDING THE SAME

(71) Applicant: Samsung Display Co., Ltd., Yongin-Si (KR)

(72) Inventors: Hyeon Bum LEE, Yongin-si (KR); Dong Uk KIM, Yongin-si (KR); Hyun Ho KIM, Yongin-si (KR); Hyoeng Ki KIM, Yongin-si (KR); Hoon Gi LEE, Yongin-si (KR)

(21) Appl. No.: 19/277,453

(22) Filed: Jul. 23, 2025

(30) Foreign Application Priority Data
Oct. 15, 2024 (KR) 10-2024-0140489

(51) Int. Cl. H10K 59/80; H10K 59/35; H10K 102/00

(52) U.S. Cl. CPC H10K 59/879; H10K 59/352; H10K 59/873; H10K 59/877; H10K 59/8792; H10K 2102/3026

(57) ABSTRACT

A display device includes a base substrate, a first unit display area and a second unit display area each of which is arranged on the base substrate and includes at least one pixel, a partial capping layer selectively covering only the at least one pixel included in the first unit display area, and a light-shielding layer on the second unit display area to separate the second unit display area from the first unit display area.

### CROSS-REFERENCE TO RELATED APPLICATION AND CLAIM OF PRIORITY

This application claims priority to Korean Patent Application No. 10-2024-0140489 filed on Oct. 15, 2024 in the Korean Intellectual Property Office (KIPO), the entire disclosure of which is incorporated by reference herein.

### TECHNICAL FIELD

Embodiments of the present disclosure relate to a display device and electronic device including the same. More particularly, embodiments of the present disclosure relate to a display device including a display area and an optical functional layer, and an electronic device including the same.

### BACKGROUND

In a display device such as an organic light emitting diode (OLED) display device and a liquid display device (LCD), a display substrate including thin film transistors (TFTs) and various wirings is provided, and a display structure including electrodes and emission layers is formed on the display substrate to provide a display panel.

Recently, a display device capable of adjusting visibility in a display area of the display device according to demands for protecting personal information has been developed.

### SUMMARY

According to an aspect of the present disclosure, there is provided a display device having improved optical and display properties.

According to an aspect of the present disclosure, there is provided an electronic device including a display device with improved optical and display properties.

A display device may include a base substrate, a first unit display area and a second unit display area, each of which is arranged on the base substrate and includes at least one pixel, a partial capping layer selectively covering only the at least one pixel included in the first unit display area, and a light-shielding layer on the second unit display area to separate the second unit display area from the first unit display area.

In some embodiments, the display device may further include a common capping layer covering both the first unit display area and the second unit display area. The partial capping layer may be disposed on the common capping layer.

In some embodiments, a refractive index of the partial capping layer and a refractive index of the common capping layer may be different from each other.

In some embodiments, a top surface of the partial capping layer has a surface roughness greater than a surface roughness of a top surface of the common capping layer.

In some embodiments, each of the first unit display area and the second unit display area may include a first pixel, a second pixel and a third pixel corresponding to different colors.

In some embodiments, the partial capping layer may commonly cover the first pixel, the second pixel and the third pixel included in the first unit display area.

In some embodiments, the light-shielding layer may include a first opening, a second opening and a third opening that are above the first pixel, the second pixel and the third pixel, respectively, included in the second unit display area.

In some embodiments, the first opening and the second opening may have an area larger than an area of the first pixel and the second pixel, respectively.

In some embodiments, a first margin gap may be defined between the first opening and the first pixel, and a second margin gap larger than the first margin gap may be defined between the second opening and the second pixel.

In some embodiments, each of the first pixel, the second pixel and the third pixel of the second unit display area may be divided into a plurality of sub-pixels.

In some embodiments, the partial capping layer may include a plurality of grains spaced apart from each other.

In some embodiments, the display device may further include an encapsulation layer between the partial capping layer and the light-shielding layer. The encapsulation layer may include a first encapsulation layer, a second encapsulation layer and a third encapsulation layer sequentially stacked from the partial capping layer. A thickness of the partial capping layer may be smaller than a thickness of the first encapsulation layer.

In some embodiments, each of the first encapsulation layer and the third encapsulation layer may include an inorganic insulating material, and the second encapsulation layer may include an organic material.

In some embodiments, the partial capping layer may partially overlap the light-shielding layer.

In some embodiments, the first unit display area may be selectively driven only in a normal mode, and the second unit display area may be commonly driven in the normal mode and a private mode.

A display device may include a base substrate, a first pixel group and a second pixel group arranged on the base substrate, and a light-scattering layer selectively covering only the first pixel group. The first pixel group may be selectively driven only in a normal mode, and the second pixel group may be commonly driven in the normal mode and a private mode.

In some embodiments, the display device may further include a common capping layer covering both the first pixel group and the second pixel group. The light-scattering layer is disposed on the common capping layer.

In some embodiments, the display device may further comprise an encapsulation layer covering the common capping layer and the light-scattering layer, and a light-shielding layer on the encapsulation layer. The light-shielding layer may have an opening that corresponds to a pixel included in the second pixel group, and does not overlap the first pixel group.

In some embodiments, a pixel area included in the second pixel group may be smaller than a pixel area included in the first pixel group.

An electronic device includes the above described display device, a memory, and a processor for executing data included in the memory to control an operation of the display device.

According to embodiments of the inventive concept, a capping layer selectively covering pixel areas included in a first unit display area among the first unit display area operating in a normal mode and a second unit display area operating in normal and private modes may be formed.

Accordingly, viewing angle and luminance properties may be improved in the normal mode, and light-shielding properties in the private mode may also be improved.

### BRIEF DESCRIPTION OF THE DRAWINGS

FIG. 1 is a schematic plan view of a display device in accordance with example embodiments.

FIG. 2 is a pixel equivalent circuit diagram of a display device in accordance with example embodiments.

FIG. 3 is a schematic plan view illustrating a pixel arrangement of a display device in accordance with example embodiments.

FIGS. 4 and 5 are schematic cross-sectional views of a display device in accordance with example embodiments.

FIG. 6 is a schematic cross-sectional view of a display device in accordance with some example embodiments.

FIG. 7 is a schematic cross-sectional view of a display device according to a comparative example.

FIG. 8 is a graph showing light emission properties of display devices of an Example and Comparative Examples in a normal mode.

FIGS. 9, 10, 11, and 12 are partially enlarged cross-sectional views illustrating display devices in accordance with example embodiments.

FIG. 13 is a schematic plan view illustrating a pixel arrangement of a display device in accordance with some example embodiments.

FIGS. 14 and 15 are a schematic plan view and a cross-sectional view, respectively, illustrating a pixel arrangement of a display device in accordance with some example embodiments

FIG. 16 is a block diagram of an electronic device in accordance with an embodiment.

FIG. 17 is a schematic diagram of an electronic device in accordance with various embodiments.

### DETAILED DESCRIPTION OF THE EMBODIMENTS

Hereinafter, embodiments of the inventive concept will be described in more detail with reference to the attached drawings. The same reference numerals can l be used for indicating the same elements in the drawings, and repeated descriptions of the same elements can be omitted. Embodiments disclosed in the attached drawings are exemplary, and is to be understood to include all modifications, equivalents and substitutes included in the spirit and technical scope of the inventive concept.

The terms “on”, “connected”, “coupled,” etc., used herein refers to a direct placement/connection/combination, and also refers to a case where another element is interposed two different elements.

The terms such as “first”, “second”, “below”, “below”, “above,” “above,” etc., are used in a relative sense to distinguish different elements or positions, and do not specify an absolute position or an absolute order.

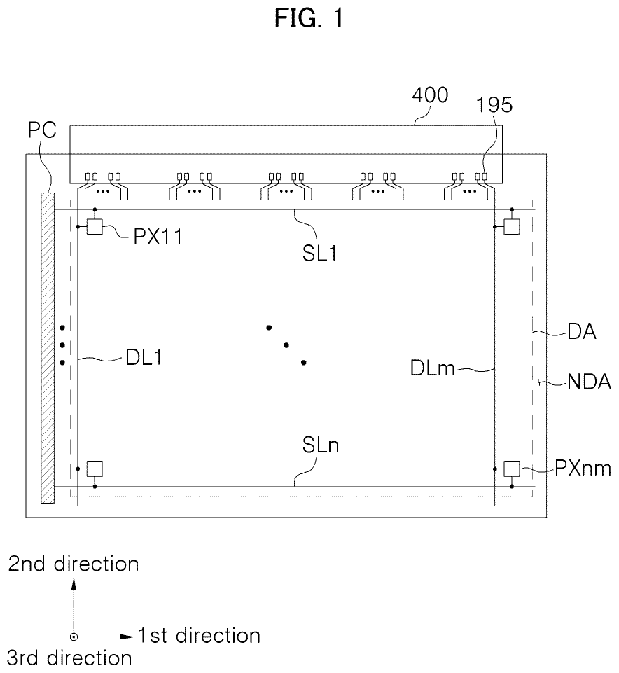

FIG. 1 is a schematic plan view of a display device in accordance with example embodiments.

In FIG. 1, a first direction and a second direction may refer to two directions parallel to a display surface of the display device and orthogonal to each other. For example, the first direction may correspond to an X-direction (a row direction) of the display device, and the second direction may correspond to a Y-direction (a column direction) of the display device. A third direction may be perpendicular to the first direction and the second direction. The third direction may correspond to a Z-direction (a thickness direction) of the display device.

In the accompanying drawings, the definition of the direction described above may be equally applied.

Referring to FIG. 1, a plurality of pixels PX11 to PXnm may be arranged in a display area DA of the display device.

In example embodiments, a pixel circuit including scan lines (or gate lines) SL1 to SLn forming first to n^{th} rows and data lines DL1 to DLm forming first to m^{th} columns may be arranged on a base substrate 100 of the display device. Each of the pixels PX11 to PXnm may be connected to a corresponding n^{th} row scan line among a plurality of scan lines SL1 to SLn and a corresponding m^{th} column data line among a plurality of data lines DL1 to DLm.

Each of the pixels PX11 to PXnm may further include a pixel circuit including a transistor and a light-emitting device as will be described below. Although not illustrated in detail in FIG. 1, the pixel circuit may further include wirings such as a power line, a ground line, etc.

FIG. 1 illustrates that the data lines DL1 to DLm extend in the second direction and the scan lines SL1 to SLn extend in the first direction, but the construction of the data lines and the scan lines is not limited to that illustrated in FIG. 1.

A peripheral circuit PC may be disposed in a non-display area NDA of the display device. For example, the peripheral circuit PC may include a gate driving circuit. The gate driving circuit may be integrated into the display device by an oxide silicon gate driver circuit (OSG) or an amorphous silicon gate driver circuit (ASG) process.

The peripheral circuit PC may further include a data driver, a gate driver, a light-emitting driver, a power voltage generator, a timing controller, or the like.

The display device may further include a printed circuit board 400. Pads 195 of the pixel circuit may be assembled at one end portion of the non-display area NDA. The printed circuit board 400 may be electrically connected to the pixel circuit through the pads 195. For example, the printed circuit board 400 may be electrically connected to the pads 195 by a heating-compression process using a conductive intermediate structure such as an anisotropic conductive film ACF.

An integrated circuit such as a data driving circuit may be disposed on the printed circuit board 400. In some embodiments, an integrated circuit chip in the form of a chip-on-film (COF) may be mounted on the printed circuit board 400.

Hereinafter, constructions/structures of the display device of the present disclosure may be described using an example of an organic light-emitting display device. However, the display device disclosed in the present application may be applied to various types of display devices such as an inorganic light-emitting display device and a quantum dot light-emitting display device,

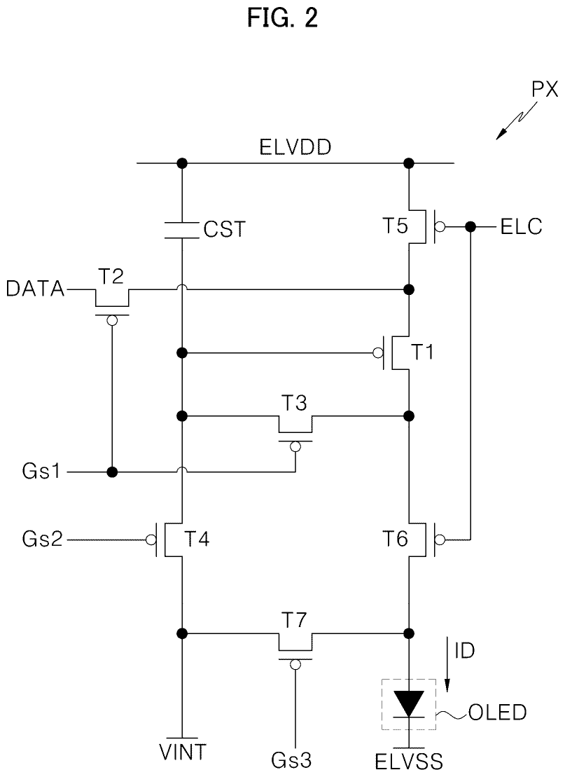

FIG. 2 is a pixel equivalent circuit diagram of a display device in accordance with example embodiments.

Referring to FIG. 2, each pixel PX may include a first transistor T1, a second transistor T2, a third transistor T3, a fourth transistor T4, a fifth transistor T5, a sixth transistor T6, a seventh transistor T7, and a storage capacitor CST.

The first transistor T1 may include a gate terminal, a first terminal and a second terminal. The gate terminal may be connected to the storage capacitor CST. The first terminal may be connected to the second transistor T2. The second terminal may be connected to the sixth transistor T6. The first transistor T1 may generate a driving current ID based on a voltage difference between the gate terminal and the first terminal. For example, the first transistor T1 may be referred to as a driving transistor.

The second transistor T2 may include a gate terminal, a first terminal, and a second terminal. The gate terminal of the second transistor T2 may receive a first gate signal Gs1. The second transistor T2 may be turned on or off in response to the first gate signal Gs1. The first terminal of the second transistor T2 may receive a data voltage DATA. The second transistor T2 may provide the data voltage DATA to the first terminal of the first transistor T1 in response to the first gate signal Gs1. For example, the second transistor T2 may be referred to as a switching transistor.

The third transistor T3 may include a gate terminal, a first terminal, and a second terminal. The gate terminal may receive the first gate signal Gs1. The first terminal may be connected to the gate terminal of the first transistor T1. The second terminal may be connected to the second terminal of the first transistor T1. The third transistor T3 may compensate for a threshold voltage of the first transistor T1. For example, the third transistor T3 may be provided as a compensation transistor.

The fourth transistor T4 may include a gate terminal, a first terminal, and a second terminal. The gate terminal may receive a second gate signal Gs2. The first terminal may be connected to the gate terminal of the first transistor T1. The second terminal may receive an initialization voltage VINT. The fourth transistor T4 may initialize the gate terminal of the first transistor T1.

The fifth transistor T5 may include a gate terminal, a first terminal, and a second terminal. The gate terminal may receive an emission control signal ELC. The first terminal may receive a high power supply voltage ELVDD. The second terminal may be connected to the first transistor T1.

The sixth transistor T6 may include a gate terminal, a first terminal, and a second terminal. The gate terminal may receive the emission control signal ELC. The first terminal may be connected to the first transistor T1. The second terminal may be connected to an organic light-emitting diode OLED. The sixth transistor T6 may transfer the driving current ID to the organic light-emitting diode OLED in response to the emission control signal ELC.

The seventh transistor T7 may include a gate terminal, a first terminal, and a second terminal. The gate terminal may receive a third gate signal Gs3. The first terminal may be connected to the organic light emitting diode (OLED). The second terminal may receive the initialization voltage VINT. The seventh transistor T7 may initialize the organic light-emitting diode OLED.

The storage capacitor CST may include a first terminal and a second terminal. The first terminal may receive the high power supply voltage ELVDD. The second terminal may be connected to the gate terminal of the first transistor T1

The organic light-emitting diode OLED may include a first terminal and a second terminal. The first terminal may be connected to the sixth transistor T6. The second terminal may be supplied with a low power supply voltage ELVSS. The organic light-emitting diode OLED may emit a light based on the driving current ID.

In FIG. 2, a structure of 7T1C is illustrated in which seven thin film transistors and one storage capacitor (CST) are included for each pixel (PX), but the pixel structure of the display device disclosed in the present application is not limited thereto.

For example, each pixel PX may include two or more transistors and may have a structure such as 2T1C, 5T1C, 5T2C, 6T1C, 6T2C, or the like.

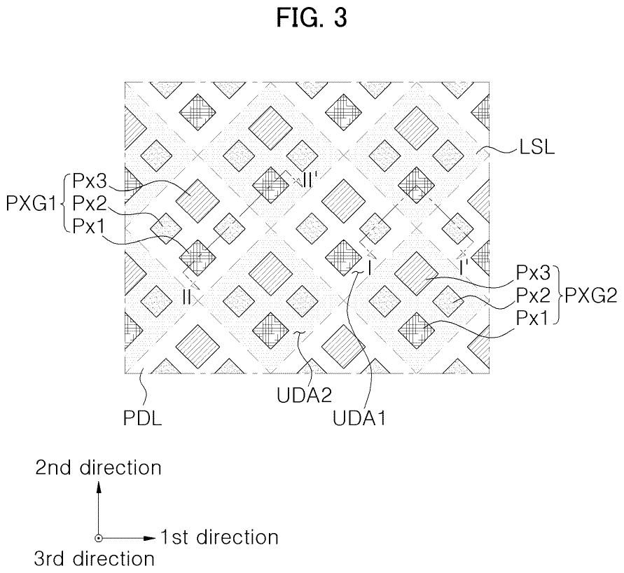

FIG. 3 is a schematic plan view illustrating a pixel arrangement of a display device in accordance with example embodiments.

Hereinafter, the term “pixel” may refer to a light-emitting region defined by a pixel defining layer PDL. For example, the pixel may refer to an area of an opening of the pixel defining layer PDL thorough which a pixel electrode is exposed.

Referring to FIG. 3, pixel groups may be arranged in the display area DA of the display device. Each pixel group may include a plurality of pixels.

The pixels may include a first pixel Px1, a second pixel Px2 and a third pixel Px3. In a non-limiting example, the first pixel Px1, the second pixel Px2 and the third pixel Px3 may correspond to a red pixel (R), a green pixel (G), and a blue pixel (B), respectively.

In some embodiments, when observed in a plan view of FIG. 3, an area of the third pixel Px3 may be greater than an area of each of the first pixel Px1 and the second pixel Px2. An area of the first pixel Px1 may be greater than an area of the second pixel Px2.

According to embodiments of the inventive concept, the display area DA may include a first unit display area UDA1 and a second unit display area UDA2. Accordingly, a top surface of the base substrate 100 may also have a first unit display area UDA1 and a second unit display area UDA2.

According to embodiments, a plurality of the first unit display areas UDA1 may be repeated in the first direction to define a first unit display area row. A plurality of the second unit display areas UDA2 may be repeated in the first direction to define a second unit display area row.

The first unit display area row and the second unit display area row may be alternately and repeatedly arranged in the second direction. Accordingly, as illustrated in FIG. 3, the first unit display area UDA1 and the second unit display area UDA2 may be alternately and repeatedly arranged in a diagonal direction with respect to the first direction and the second direction.

In an embodiment, each of the first unit display area UDA1 and the second unit display area UDA2 may have a rhombus shape. The first unit display area UDA1 and the second unit display area UDA2 may be distinguished from each other by a light-shielding layer LSL selectively formed in the second unit display area UDA2.

Each of the first unit display area UDA1 and the second unit display area UDA2 may include at least one pixel. In example embodiments, the first unit display area UDA1 and the second unit display area UDA2 may include a first pixel group PXG1 and a second pixel group PXG2, respectively. The first pixel group PXG1 and the second pixel group PXG2 may include the first pixel Px1, the second pixel Px2 and the third pixel Px3 as described above.

In an embodiment, each of the first pixel Px1, the second pixel Px2 and the third pixel Px3 may have a rhombus shape. In an embodiment, each of the first pixel Px1, the second pixel Px2 and the third pixel Px3 may be adjacent to vertex portions of the unit display area.

The first pixel Px1 and the third pixel Px3 may be adjacent to vertices of the unit display area in the second direction. A pair of second pixels Px2 may be adjacent to vertices of the unit display area in the first direction.

The shape/arrangement of the above-described pixels and the shape/arrangement of the unit display area correspond to a non-limiting example, and may be appropriately changed/adjusted in consideration of light-emitting properties and luminance/viewing angle of the display device.

According to embodiments of the present disclosure, the first unit display area UDA1 and the second unit display area UDA2 may correspond to sub-display areas that may operate or emit light together in a first driving mode. The second unit display area UDA2 may be a sub-display area that may operate or emit light in a second driving mode.

In example embodiments, the first driving mode and the second driving mode may correspond to a normal mode (or a common mode) and a private mode, respectively. In the private mode, the first unit display areas UDA1 may not be driven or operated, and only the second unit display areas UDA2 may be selectively driven or operated.

In the normal mode, substantially all unit display areas may be selected to provide wide viewing angles in all directions. In the private mode, the viewing angle may be limited. For example, in the private mode, a side view may become narrow or may be blocked compared to that in the normal mode.

For example, in the above private mode, luminance may be additionally reduced by the light-shielding layer LSL, and the viewing angle may also be reduced to prevent personal information exposure.

For example, a controller included in the peripheral circuit PC may generate a selection signal in the normal mode or in the private mode, and a control signal may be generated to operate the display device in the normal mode or in the private mode according to the selection signal.

In the normal mode, all of the first to third pixels Px1, Px2, and Px3 included in the first and second pixel groups PXG1 and PXG2 of the display area DA may be selected by a scan signal to emit light with a luminance of a corresponding data signal.

In the private mode, the first to third pixels Px1 Px2, and Px3 included in the first unit display area UDA1 or the first pixel group PXG1 of the display area DA may not emit light (a non-emission), and only the first to third pixels Px1 to Px3 included in the second unit display area UDA2 or the second pixel group PXG2 may be selected to emit light with a luminance of a corresponding data signal.

The non-emission of the pixel may include a case in which a data signal is not applied because the corresponding pixel is not selected by a scan signal, or a case in which the corresponding pixel is selected by the scan signal to receive a black data signal and express black.

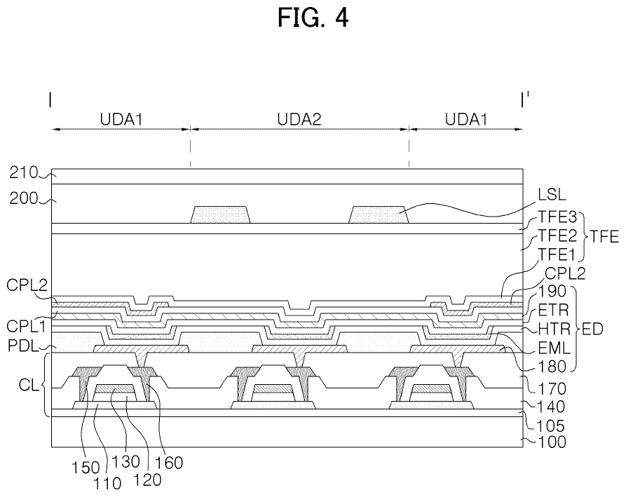

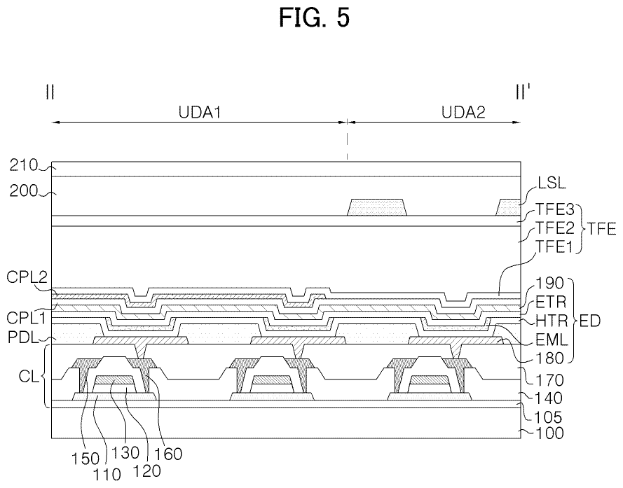

FIGS. 4 and 5 are schematic cross-sectional views of a display device in accordance with example embodiments. Specifically, FIG. 4 is a cross-sectional view taken along a line I-I′ of FIG. 3 in a thickness direction. FIG. 5 is a cross-sectional view taken along a line II-II′ of FIG. 3 in a thickness direction.

Referring to FIGS. 4 and 5, the display device may include a base substrate 100, a circuit layer CL, a light-emitting device ED, and insulating layers (a capping layer, a pixel defining layer, an encapsulation layer, etc.).

The base substrate 100 may be provided as a back-plane substrate of a display device. A glass substrate or a plastic substrate may be used as the base substrate 100. In some embodiments, the base substrate 100 may include a polymer material having transparency and flexibility. In this case, the base substrate 100 may be used in a transparent flexible display device.

For example, the base substrate 100 may include a polymer material such as polyimide, polysiloxane, an epoxy resin, an acrylic resin, polyester, or the like. In an embodiment, the base substrate 100 may include polyimide.

A buffer layer 105 may be formed on a top surface of the base substrate 100. Moisture penetrating through the base substrate 100 may be blocked by the buffer layer 105, and diffusion of impurities between structures formed on the base substrate 100 and the base substrate 100 may be blocked. The buffer layer 105 may be formed entirely over the display area DA and the non-display area NDA of the base substrate 100, and may entirely cover the top surface of the base substrate 100.

The buffer layer 105 may include, e.g., an inorganic insulating material such as silicon oxide, silicon nitride or silicon oxynitride. These may be used alone or in a combination of two or more therefrom. In some embodiments, the buffer layer 105 may have a stacked structure including a silicon oxide layer and a silicon nitride layer. The buffer layer 105 may be formed by a deposition process such as a chemical vapor deposition (CVD) process, a sputtering process, an atomic layer deposition (ALD) process, or the like, to include the inorganic insulating material as described above.

In some embodiments, the buffer layer 105 may include an organic layer, and may have a multi-layered structure of an organic layer and an inorganic layer.

The circuit layer CL may include the above-described data lines and scan lines, and transistors formed on the base substrate 100 or the buffer layer 105. The transistor may be electrically connected to the light-emitting device ED.

The transistor may include an active layer 110, a gate insulation layer 120, a gate electrode 130, and connection electrodes 150 and 160.

The active layer 110 may be disposed on the buffer layer 105, and may be patterned by, e.g., a photo-lithography process so that each pixel may be repeatedly/regularly arranged. The active layer 110 may include a silicon compound such as polysilicon or amorphous silicon. A p-type dopant or an n-type dopant may be doped in a partial region of the active layer 110, and the active layer 110 may include a source region, a drain region, and a channel region.

The active layer 110 may include an oxide semiconductor such as indium gallium zinc oxide (IGZO), zinc tin oxide (ZTO), or ITZO.

The gate insulation layer 120 may be formed on the active layer 110, and the gate electrode 130 may be stacked on the gate insulation layer 120. As illustrated in FIG. 5, the gate insulation layer 120 may be formed in a pattern shape partially covering each active layer 110.

In an embodiment, the gate insulation layer 120 may extend continuously over a plurality of the pixels or light-emitting regions, and may be commonly included in a plurality of the transistors.

The gate electrode 130 may overlap the channel region of the active layer 110 in the third direction. A scan signal may be transmitted from the scan line through the gate electrode 130.

The gate insulation layer 120 may be formed by the above-described deposition process to include an inorganic insulating material such as silicon oxide, silicon nitride, silicon oxynitride, or the like. In some embodiments, the gate insulation layer 120 having a patterned shape may be formed as illustrated in FIG. 4 by a photo-lithography process in which the gate electrode 130 may be substantially used as an etching mask.

In some embodiments, the source region and the drain region may be formed in the active layer 110 using the gate electrode 130 and the gate insulation layer 120 as an ion implantation mask.

An insulating interlayer 140 covering the gate insulation layer 120 and the gate electrode 130 may be formed on the active layer 110. The connection electrodes 150 and 160 which may be in contact with or electrically connected to the active layer 110 may be formed on the insulating interlayer 140.

The insulating interlayer 140 may be formed by the above-described deposition process to include an inorganic insulating material such as silicon oxide, silicon nitride, and silicon oxynitride. The insulating interlayer 140 may be formed in a single-layered structure or a multi-layered structure including different materials.

In some embodiments, when the active layer 110 includes an oxide semiconductor, hydrogen (H) contained in the insulating interlayer 140 may be diffused or transferred to the active layer 110 through a heat treatment process when forming the insulating interlayer 140. Accordingly, a carrier concentration may be increased by hydrogen, and thus the source region and the drain region having increased conductivity may be formed at lateral portions of the active layer 110.

The connection electrodes 150 and 160 may penetrate the insulating interlayer 140, and may be connected to the active layer 110. When the gate insulating layer 120 is continuously formed commonly in a plurality of the light-emitting regions, the connection electrodes 150 and 160 may also penetrate the gate insulation layer 120.

The connection electrodes 150 and 160 may include a source electrode 150 connected to or in contact with the source region of the active layer 110, and a drain electrode 160 connected to or in contact with the drain region of the active layer 110.

Contact holes may be formed by partially etching the insulating interlayer 140. For example, the contact holes exposing the source region and the drain region, respectively, may be formed. A metal layer sufficiently filling the contact holes may be formed on the insulating interlayer 140, and then the metal layer may be partially etched to form the source electrode 150 and the drain electrode 160. For example, the data signal may be transferred from the data line through the source electrode 150.

The gate electrode 130 and the connection electrodes 150 and 160 may include a metal such as Ag, Mg, Al, W, Cu, Ni, Cr, Mo, Ti, Pt, Ta, Nd and Sc, an alloy thereof, or a nitride thereof. The gate electrode 130 and the connection electrodes 150 and 160 may be formed by the above-described deposition process.

A planarization layer 170 covering the connection electrodes 150 and 160 may be formed on the insulating interlayer 140. The planarization layer 170 may accommodate a via structure electrically connecting a pixel electrode 180 and the drain electrode 160.

In some embodiments, the planarization layer 170 may include an organic material such as polyimide, an epoxy resin, an acrylic resin, polyester, a siloxane resin, a benzocyclobutene (BCB), or the like. The planarization layer 170 may be formed by the above-described deposition process or a spin coating process.

The pixel electrode 180 may be formed in each pixel to be electrically connected to the transistor. The pixel electrode 180 may be formed on the planarization layer 170 to be electrically connected to the drain electrode 160.

For example, the planarization layer 170 may be partially etched to form a via hole exposing a top surface of the drain electrode 160. A conductive layer sufficiently filling the via hole and including a metal material or a transparent conductive oxide may be formed on a top surface of the planarization layer 170, and then the conductive layer may be partially etched to form the pixel electrode 180.

The pixel electrode 180 may serve as anode, and may include a high work function conductive material capable of promoting hole injection. The pixel electrode 180 may be provided as a transmissive electrode. The pixel electrode 180 may include a transparent conductive oxide such as indium tin oxide (ITO), indium zinc oxide (IZO), zinc oxide (ZnO) and indium tin oxide (ITZO).

The pixel electrode 180 may be provided as a translucent electrode or a reflective electrode. The pixel electrode 180 may include a metal selected from Ag, Mg, Cu, Al, Pt, Pd, Au, Ni, Nd, Ir, Cr, Li, Ca, LiF, Mo, Ti, W, In, Sn and Zn, or an alloy of two or more therefrom.

The pixel electrode 180 may have a single-layered structure or a multi-layered structure. For example, the pixel electrode 180 may have a triple-layered structure of ITO/Ag/ITO or ITO/Al/ITO.

A pixel defining layer PDL exposing a top surface of the pixel electrode 180 may be formed on the planarization layer 170. The pixel defining layer PDL may be formed to at least partially expose the top surface of the pixel electrode 180, and thus the pixel may be defined. The pixel defining layer PDL may cover a peripheral portion of the pixel electrode 180.

For example, a pixel region or a light-emitting region may be defined by a sidewall of the pixel defining layer PDL. The first pixel Px1, the second pixel Px2, and the third pixel Px3 may be separated from each other and defined by the pixel defining layer PDL.

The pixel defining layer PDL may include, e.g., an organic material such as a polysiloxane resin, a polyimide resin, an acrylic resin, or the like. The pixel defining layer PDL may include a colorant material such as a black pigment/dye dispersed in a resin material.

The pixel defining layer PDL may be commonly formed in the first unit display area UDA1 and the second unit display area UDA2. Accordingly, the first pixels Px1, the second pixels Px2 and the third pixels Px3 may be formed commonly in the first unit display area UDA1 and the second unit display area UDA2 by the pixel defining layer PDL.

An emission layer EML may be disposed on the exposed surface of the pixel electrode 180. In some embodiments, the emission layer EML may include an organic light-emitting material independently patterned for each of a red pixel, a green pixel, and a blue pixel to generate a light of a different color for each pixel.

For example, the organic light-emitting material may include a host material excited by a hole and an electron, and a dopant material for increasing a luminous efficiency through absorption and release of energy.

In some embodiments, a hole transfer region HTR may be disposed between the pixel electrode 180 and the emission layer EML. The hole transfer region HTR may include a hole transport layer (HTL) and/or a hole injection layer (HIL).

An electron transfer region ETR may be disposed on the emission layer EML. The electron transfer region ETR may include an electron transport layer (ETL) and/or an electron injection layer (EIL).

The hole transfer region HTR and the electron transfer region ETR may extend commonly and continuously over a plurality of the light-emitting regions or the pixels.

For example, the hole transfer region HTR may include an electron transport material such as m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N, N′-di(naphthalene-1-yl)-N, N′-diphenyl-benzidine), TPD (N, N′-bis(3-methylphenyl)-N, N′-diphenyl-[1,1′-biphenyl]-4,4′-diamine), TCTA (4,4′,4″-tris(N-carbazolyl)triphenylamine),PEDOT/PSS (poly(3,4-ethylenedioxythiophene)/poly(4-styrenesulfonate)), etc.

For example, the electron transfer region ETR may include an electron transport material such as an anthracene-based compound, Alq3 (tris(8-hydroxyquinolinato)aluminum), TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), etc.

The emission layer EML, the hole transfer region HTR and/or the electron transfer region ETR may be formed by a process such as a thermal deposition, a vacuum deposition, a spin coating, an inkjet printing, a laser printing, a casting, a laser thermal transfer, etc.

A counter electrode 190 may be disposed on the pixel defining layer PDL and the emission layer EML. The counter electrode 190 may be formed on top surfaces of the pixel defining layer PDL and the electron transfer region ETR.

The counter electrode 190 may be a common electrode that is provided commonly and continuously in a plurality of the light-emitting regions or the pixels.

The counter electrode 190 may serve as an electron injection electrode or a cathode. The counter electrode 190 may include a metal, an alloy, an electrically conductive compound, etc., having a low work function.

For example, the counter electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, etc. These may be used alone or in a combination of two or more therefrom.

The counter electrode 190 may be provided as a transmissive electrode, a translucent electrode or a reflective electrode. The counter electrode 190 may have a single-layered structure or a multi-layered structure. The light-emitting device ED may be defined by a stacked structure of the pixel electrode 180, the hole transfer region HTR, the emission layer EML, the electron transfer region ETR, and the counter electrode 190 described above. For example, the light-emitting device ED may be electrically connected to each transistor through the drain electrode 160, and may be provided for each pixel Px1, Px2 and Px3.

According to embodiments of the present disclosure, a capping layer may be formed on the pixels or the light-emitting devices ED. In example embodiments, the capping layer may include a partial capping layer CPL2 that may selectively cover the first pixel group PXG1 included in the first unit display area UDA1. The capping layer may further include a common capping layer CPL1 that may commonly cover the first unit display area UDA1 and the second unit display area UDA2.

In some embodiments, the common capping layer CPL1 may be formed on the counter electrode 190. As described above, the common capping layer CPL1 may cover both the first unit display area UDA1 and the second unit display area UDA2. The common capping layer CPL1 may commonly cover the pixels included in the first pixel group PXG1 and the pixels included in the second pixel group PXG2.

The common capping layer CPL1 may be formed continuously throughout a plurality of the first unit display areas UDA1 and the second unit display areas UDA2, and may commonly cover the pixels included in the first pixel groups PXG1 and the pixels included in the second pixel groups PXG2.

The partial capping layer CPL2 may be formed on the common capping layer CPL1. The pixels of the second pixel group PXG2 included in the second unit display area UDA2 may not be covered by the partial capping layer CPL2. The partial capping layer CPL2 may selectively cover only the pixels of the first pixel group PXG1 included in the first unit display area UDA1.

In some embodiments, as illustrated in FIG. 4, the partial capping layer CPL2 may not substantially extend to the second unit display area UDA2.

As illustrated in FIG. 5, the partial capping layer CPL2 may continuously and commonly cover the first pixel Px1, the second pixel Px2, and the third pixel Px3 of the first pixel group PXG1 included in the first unit display area UDA1. Accordingly, an area covered by the partial capping layer CPL2 may be substantially defined as the first unit display area UDA1.

External luminous efficiency in each light-emitting region may be enhanced by the capping layers CPL1 and CPL2 described above. For example, the common capping layer CPL1 may include a material having a refractive index greater than or equal to 1.6 (e.g., with respect to a light having a wavelength of 589 nm). The capping layers CPL1 and CPL2 may include an inorganic material (e.g., silicon oxide, silicon nitride, silicon oxynitride, metal oxide, etc.). The capping layers CPL1 and CPL2 may include an organic material, and may be formed of a hybrid material layer including an organic material and an inorganic material.

According to embodiments of the present disclosure, light-scattering properties of light generated in the first unit display area UDA1 may be increased by the partial capping layer CPL2. The partial capping layer CPL2 may serve as a light-scattering layer having an increased light-scattering ratio or light-scattering property compared to that of the common capping layer CPL1.

Accordingly, in the normal mode, an intensity of an inclined light in a lateral direction in the first unit display area UDA1 may be increased relatively to an intensity of a straight light. Thus, a side color shift phenomenon may be suppressed and white angular difference (WAD) may be reduced.

In an embodiment, the partial capping layer CPL2 may include scattering particles (titania, silica, zirconia, alumina, etc.). Accordingly, the light-scattering properties by the partial capping layer CPL2 may be increased. In an embodiment, refractive indices of the partial capping layer CPL2 and the common capping layer CPL1 may be different from each other. Accordingly, a light-scattering at an interface between the capping layers may be further improved.

An encapsulation layer TFE may be formed on the capping layers CPL1 and CPL2. The light-emitting devices ED may be protected from moisture or oxygen by the encapsulation layer TFE.

The encapsulation layer TFE may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE), or any combination thereof; or a combination of inorganic and organic layers.

In example embodiments, the encapsulation layer TFE may include a first encapsulation layer TFE1, a second encapsulation layer TFE2, and a third encapsulation layer TFE3 are sequentially stacked from the capping layers CPL1 and CPL2. The first encapsulation layer TFE1 and the third encapsulation layer TFE3 may be the inorganic layer, and may be formed by a deposition process such as a CVD process.

The second encapsulation layer TFE2 may be formed by a coating process such as a spin coating process to include the organic resin material as described above. A thickness of the second encapsulation layer TFE2 may be greater than each thickness of the first encapsulation layer TFE1 and the third encapsulation layer TFE3, and may be provided as a substantially planarization layer in the display area DA.

The light-shielding layer LSL may be disposed on the third encapsulation layer TFE3. As described with reference to FIG. 3, the second unit display area UDA2 may be substantially divided or defined from the first unit display area UDA1 by the light-shielding layer LSL.

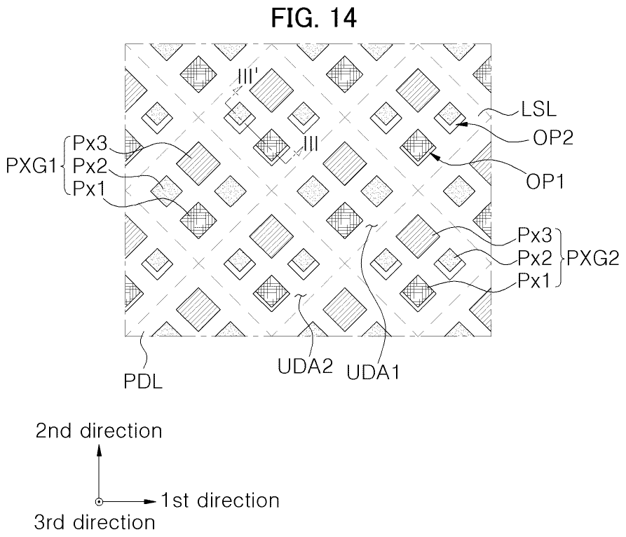

As will be described later in FIG. 14, the light-shielding layer LSL may include an opening overlapping pixels of the second pixel group PXG2 included in the second unit display area UDA2.

The light-shielding layer LSL may be a resin layer including a light-shielding colored material such as a black colored material. For example, the light-shielding layer LSL may include a photosensitive binder resin and the light-shielding colored material, and may be selectively formed only in the second unit display area UDA2 to include the opening by a photo-lithography process.

The light-shielding layer LSL may include color filter layers overlapping each other. In example embodiments, two or more color filter layers of different colors may overlap to substantially serve as the light-shielding layer LSL. In an embodiment, two of a red color filter layer, a green color filter layer and a blue color filter layer may overlap in the third direction to serve as the light-shielding layer LSL. In an embodiment, the red color filter layer, the green color filter layer and the blue color filter layer may overlap to serve as the light-shielding layer LSL.

A lateral light emitted to the second unit display area UDA2 in the private mode may be blocked or limited by the light-shielding layer LSL. Accordingly, a viewing angle in the private mode may be reduced, and personal information exposure may be more effectively prevented.

A passivation layer 200 covering the light-shielding layer LSL may be formed on the encapsulation layer TFE. The passivation layer 200 may be continuously formed commonly over a plurality of the first unit display areas UDA1 and the second unit display areas UDA2.

In some embodiments, the passivation layer 200 may include, e.g., a light-transmitting inorganic material or organic material having a high refractive index of 1.4 or more, 1.5 or more, 1.6 or more, or 1.7 or more, and may have a single-layered structure or a multi-layered structure. The passivation layer 200 may be formed on the light-shielding layer LSL to more effectively block the lateral light in the second unit display area UDA2.

An optical layer 210 may be disposed on the passivation layer 200. For example, the optical layer 210 may include a polarizing plate, a retardation layer, an anti-reflective layer, a hard coating layer, or a window film.

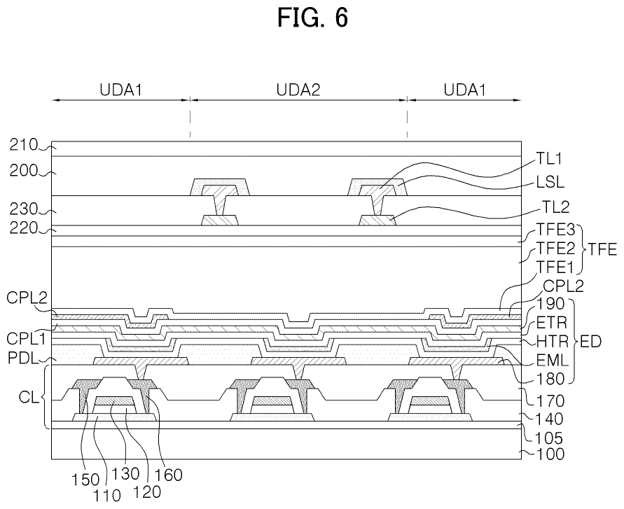

FIG. 6 is a schematic cross-sectional view of a display device in accordance with some example embodiments.

Referring to FIG. 6, a touch sensor layer may be added on the encapsulation layer TFE. In some embodiments, the touch sensor layer may include sensor electrode layers TL1 and TL2 having an on-cell type structure.

In some embodiments, a touch buffer layer 220 may be disposed on the encapsulation layer TFE, and the second sensor electrode layer TL2 and the first sensor electrode layer TL1 may be disposed on the touch buffer layer 220. The second sensor electrode layer TL2 and the first sensor electrode layer TL1 may be disposed at different levels with a sensor insulating interlayer 230 interposed therebetween.

The touch buffer layer 220 may be provided as a base layer of the second sensor electrode layer TL2, and may be directly formed on the encapsulation layer TFE. The sensor insulating interlayer 230 may be provided as a base layer of the first sensor electrode layer TL1, and may be formed on the touch buffer layer 220 and the second sensor electrode layer TL2.

In some embodiments, the first sensor electrode layer TL1 may include a plurality of sensing electrode patterns. The second sensor electrode layer TL2 may include connection electrodes or bridge electrodes electrically connecting some of the sensing electrode patterns to each other.

In some embodiments, the first sensor electrode layer TL1 may include the connection electrodes or the bridge electrodes, and the second sensor electrode layer TL2 may include the sensing electrode patterns.

The touch buffer layer 220 and the sensor insulating interlayer 230 may include an inorganic insulating material such as silicon oxide, silicon nitride, and/or silicon oxynitride, or an organic insulating material. The sensor electrode layers TL1 and TL2 may include a metal or a transparent conductive oxide such as ITO. In an embodiment, the sensing electrode patterns may have a mesh structure to have an improved light transmittance.

In some embodiments, the first sensor electrode layer TL1 and the second sensor electrode layer TL2 may overlap the pixel defining layer PDL and may not overlap the pixels Px1, Px2 and Px3.

The light-shielding layer LSL may cover the first sensor electrode layer TL1 on the sensor insulating interlayer 230. For example, the light-shielding layer LSL may cover the sensing electrode patterns included in the first sensor electrode layer TL1. Thus, light reflection and light path disturbance due to the sensing electrode patterns may be prevented, and light straightness in the second unit display area UDA2 may be maintained or enhanced.

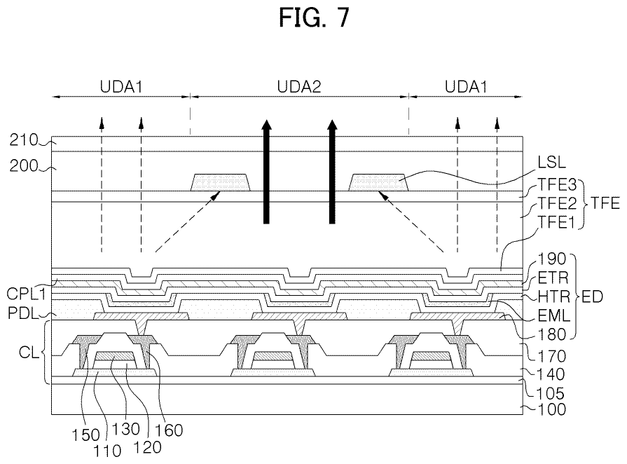

FIG. 7 is a schematic cross-sectional view of a display device according to a comparative example.

Referring to a comparative example of FIG. 7, a common capping layer CPL1 covering the light emitting devices ED may be formed, the above-described partial capping layer CPL2 may be omitted, and the encapsulation layer TFE may cover the common capping layer CPL1.

In this case, light extraction efficiency may be increased by the common capping layer CPL1 having a high refractive index, and light straightness properties in the second unit display area UDA2 may be improved as indicated by a bold arrow.

However, the lateral light in the first unit display area UDA1 operated in the normal mode may be reduced, and viewing angle properties may be deteriorated. As indicated by the inclined dotted arrow of FIG. 7, the lateral light generated in the first unit display area UDA1 may be blocked by the light-shielding layer LSL. Accordingly, lateral light emission properties in the normal mode may be further degraded, and luminance may also be lowered.

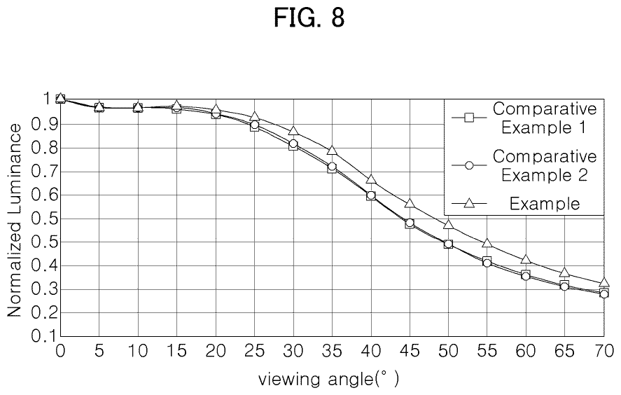

FIG. 8 is a graph showing light emission properties of display devices of an Example and Comparative Examples in a normal mode.

Specifically, a Comparative Example 1 of FIG. 8 represents an OLED display according to the comparative example of FIG. 7, and a Comparative Example 2 represents an in-plane switching (IPS) mode liquid crystal display. The Example of FIG. 8 represents an OLED display device including the common capping layer CPL1 and the partial capping layer CPL2 as described with reference to FIGS. 3 to 5.

Referring to FIG. 8, the Comparative Example 1 and the Comparative Example 2 provide substantially similar levels of viewing angle and luminance. In the Example, increased viewing angle and luminance properties may be provided compared to those from the Comparative Examples.

As described above, light scattering properties in the first unit display area UDA1 may be selectively increased and an intensity of the lateral light may be increased by the partial capping layer CPL2. Further, a light obliquely emitted from the first unit display area UDA1 may be additionally scattered, so that a light-shielding in the normal mode due to the light-shielding layer LSL may be reduced. Accordingly, overall viewing angle and luminance characteristics in the normal mode may be both improved.

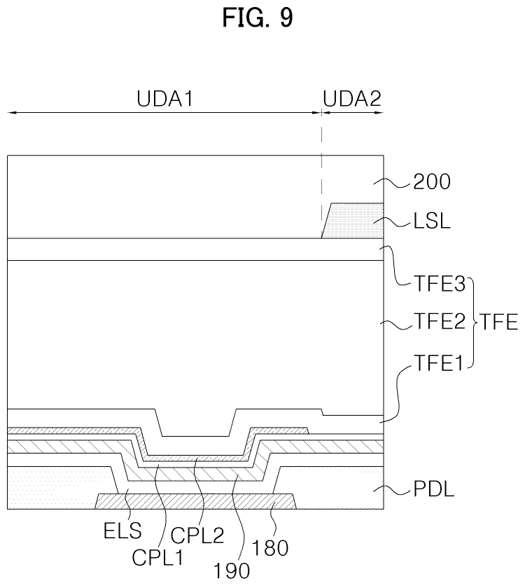

FIGS. 9 to 12 are partially enlarged cross-sectional views illustrating display devices in accordance with example embodiments. Detailed descriptions on elements and structures substantially the same as or similar to those described with reference to FIGS. 3 to 5 are omitted herein. In FIGS. 9 to 12, a stacked structure including the emission layer EML between the pixel electrode 180 and the counter electrode 190 is designated as a light-emitting stack ELS.

Referring to FIG. 9, thicknesses of the capping layers CPL1 and CPL2 may be less than a thickness of the first encapsulation layer TFE1. In some embodiments, each thickness of the common capping layer CPL1 and the partial capping layer CPL2 may be less than that of the first encapsulation layer TFE1.

The thickness of the partial capping layer CPL2 may be ½ or less of the thickness of the first encapsulation layer TFE1. In an embodiment, the thickness of the partial capping layer CPL2 may be ⅓ or less, ¼ or less, ⅕ or less, ⅙ or less, 1/7 or less, ⅛ or less, 1/9 or less, or 1/10 or less of the thickness of the first encapsulation layer TFE1.

The thickness of the common capping layer CPL1 may also be ½ or less, ⅓ or less, ¼ or less, ⅕ or less, ⅙ or less, 1/7 or less, ⅛ or less, 1/9 or less, or 1/10 or less of the thickness of the first encapsulation layer TFE1.

For example, the thicknesses of the common capping layer CPL1 and the partial capping layer CPL2 may be greater than or equal to 1/100 or greater than or equal to 1/50 of the thickness of the first encapsulation layer TFE1.

In the above-described thickness range, light-shielding properties in the private mode and light-scattering properties in the normal mode may both be effectively implemented by the common capping layer CPL1 and the partial capping layer CPL2.

In an embodiment, the thickness of the partial capping layer CPL2 may be greater than the thickness of the common capping layer CPL1. In this case, the light-scattering properties from the first unit display area UDA1 in the normal mode may be increased more easily.

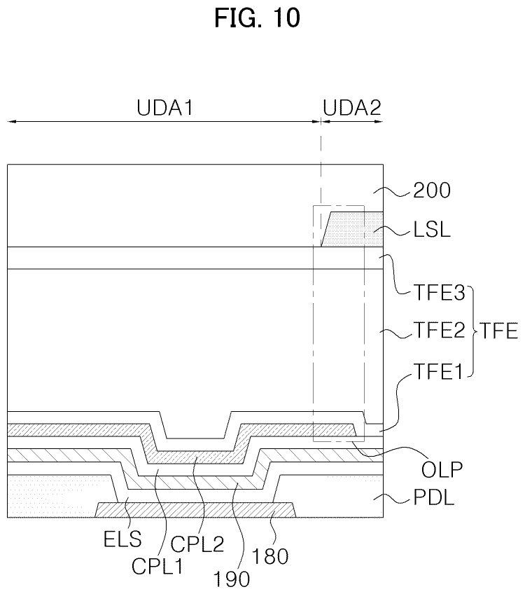

Referring to FIG. 10, the partial capping layer CPL2 may be partially included in the second unit display area UDA2. As illustrated in FIG. 10, a peripheral portion or an end portion of the partial capping layer CPL2 may extend to the second unit display area UDA2 to overlap the light-shielding layer LSL in the third direction.

Accordingly, the second unit display area UDA2 may include an overlapping portion OLP at which the partial capping layer CPL2 and the light-shielding layer LSL overlap each other. As described above, the partial capping layer CPL2 may overlap the light-shielding layer LSL, and may not cover the pixels Px1, Px2 and Px3 included in the second pixel group PXG2.

Thus, a light from the first unit display area UDA1 may be guided to be emitted through openings OP1 and OP2 (see FIG. 14) by the partial capping layer CPL2 without shielding a light generated by the second pixel group PXG2. Thus, the luminance and the viewing angle may be enhanced while preventing or reducing the light-shielding in the normal mode by the light-shielding layer LSL illustrated in FIG. 7.

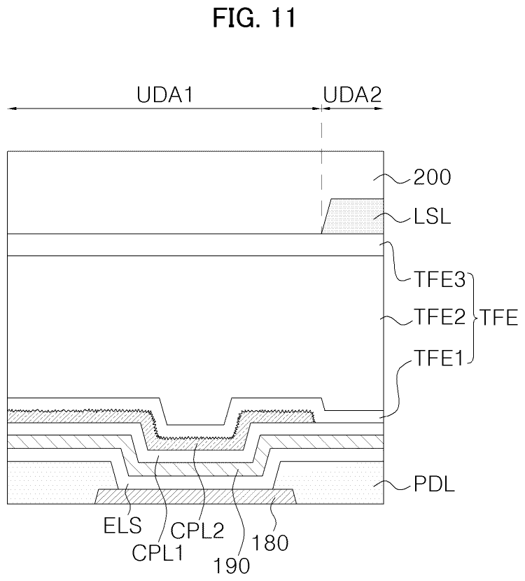

Referring to FIG. 11, a surface roughness of the partial capping layer CPL2 may be greater than a surface roughness of the common capping layer CPL1. For example, a surface roughness of a top surface of the partial capping layer CPL2 may be greater than that of a top surface of the common capping layer CPL1. In an embodiment, the top surface of the partial capping layer CPL2 may have a roughness-treated shape. In an embodiment, irregularities may be distributed on the top surface of the partial capping layer CPL2.

Accordingly, the light-scattering properties may be additionally improved through the roughness or the irregularities on the top surface of the partial capping layer CPL2, and the viewing angle properties may be further improved.

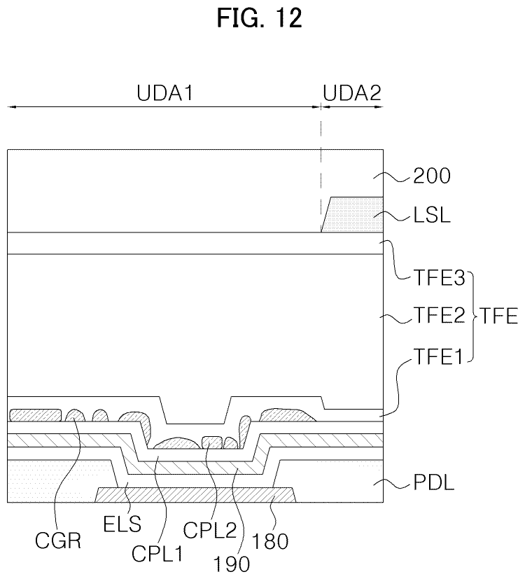

Referring to FIG. 12, the partial capping layer CPL2 may include a plurality of grains CGR.

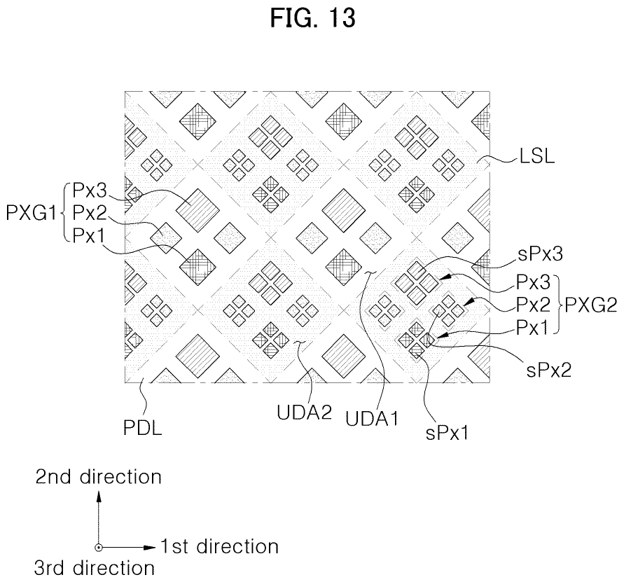

According to an embodiment of FIG. 13, the separated grains CGR having an aggregate shape or a particle shape may be distributed on the common capping layer CPL1 in the first unit display area UDA1 to form the partial capping layer CPL2.

For example, a space between the adjacent grains CGR may act as a scattering slit, thereby further enhancing a lateral light-emission property generated from the first unit display area UDA1 in the normal mode. Accordingly, degradation of the viewing angle and the luminance by the light-shielding layer LSL may be more effectively prevented, and light-emission properties in the normal mode may be further improved.

FIG. 13 is a schematic plan view illustrating a pixel arrangement of a display device in accordance with some example embodiments. Detailed descriptions on elements and structures substantially the same as or similar to those described with reference to FIG. 3 are omitted herein.

Referring to FIG. 13, each of the pixels Px1, Px2 and Px3 of the second pixel group PXG2 included in the second unit display area UDA2 may be divided into sub-pixels. For example, the first pixel Px1 of the second pixel group PXG2 may be divided into a plurality of first sub-pixels sPx1. The second pixel Px2 of the second pixel group PXG2 may be divided into a plurality of second sub-pixels sPx2. The third pixel Px3 of the second pixel group PXG2 may be divided into a plurality of third sub-pixels sPx3.

In some embodiments, the first pixel Px1, the second pixel Px2, and the third pixel Px3 of the second pixel group PXG2 may be divided into four first sub-pixels sPx1, four second sub-pixels sPx2, and four third sub-pixels sPx3, respectively.

Pixels in the second unit display area UDA2 driven alone in the private mode into the sub-pixels, so that a pixel region or a light-emitting region may be relatively reduced compared to that in the first unit display area UDA1. Further, an area of the light-shielding layer LSL may be relatively increased.

Accordingly, lateral light diffusion in the second unit display area UDA2 may be more effectively blocked, and desired light-emission properties in the private mode may be efficiently implemented.

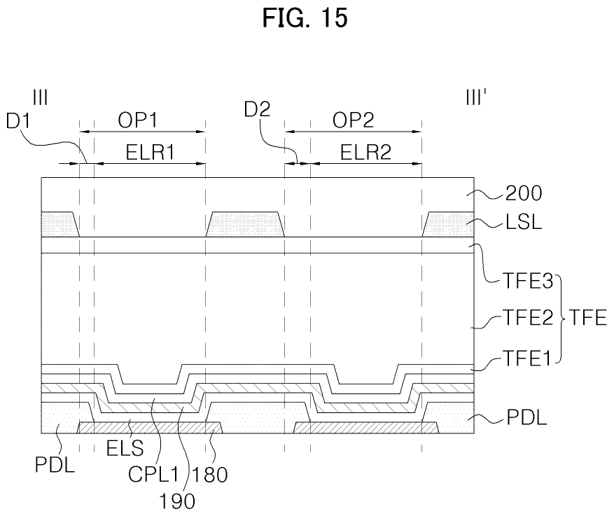

FIGS. 14 and 15 are a schematic plan view and a cross-sectional view, respectively, illustrating a pixel arrangement of a display device in accordance with some example embodiments. Specifically, FIG. 15 is a cross-sectional view taken along a line III-III′ of FIG. 14 in a third direction. Detailed descriptions on elements and structures substantially the same as or similar to those described with reference to FIGS. 3 to 5 are omitted herein.

Referring to FIGS. 14 and 15, as described above, the opening overlapping each pixel may be defined in the second unit display area UDA2 by the light-shielding layer LSL.

For example, the first opening OP1 overlapping the first pixel Px1 of the second pixel group PXG2 and the second opening OP2 overlapping the second pixel Px2 of the second pixel group PXG2 may be included in the light-shielding layer LSL. Although not illustrated in FIG. 14, a third opening overlapping the third pixel Px3 of the second pixel group PXG2 may be included in the light-shielding layer LSL.

As described above, the first pixel Px1, the second pixel Px2, and the third pixel Px3 may correspond to a red pixel R, a green pixel G and a blue pixel B, respectively.

Each of the first opening OP1 and the second opening OP2 may have an area larger than an area of the first pixel Px1 and the second pixel Px2, respectively. As illustrated in FIG. 15, the light-emitting area may be defined by an edge of the pixel defining layer PDL which may be in contact with the pixel electrode 180. The first pixel Px1 may have a first light-emitting region ELR1, and the second pixel Px2 may have a second light-emitting region ELR2.

The first opening OP1 and the second opening OP2 may substantially completely cover the first emission region ELR1 and the second emission region ELR2, respectively, and may further include a margin region.

As illustrated in FIG. 15, a first margin gap D1 may be formed between the first opening OP1 and the first emission region ELR1, and a second margin gap D2 may be formed between the second opening OP2 and the second emission region ELR2. In some embodiments, the second margin gap D2 may be greater than the first margin gap D1.

The margin gap may refer to a horizontal distance between an edge at which the light-shielding layer LSL contacts the encapsulation layer TFE and an edge at which the pixel defining layer PDL contacts the pixel electrode 180 in the cross section of FIG. 15.

According to the above-described embodiments, a size of a light-emitting opening in the second pixel Px2 provided as the green pixel G may be relatively increased. Accordingly, excessive decrease in luminance in the green pixel G at which a color property degradation may easily occur may be prevented.

In some embodiments, an area of the third pixel Px3 corresponding to the blue pixel B which may be relatively strong in the color property degradation may be substantially the same as the third opening. Accordingly, light diffusion in the private mode may be effectively blocked.

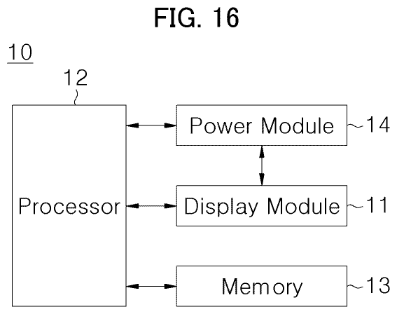

FIG. 16 is a block diagram of an electronic device 10 in accordance with an embodiment.

Referring to FIG. 16, the electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power required for the operation of the electronic device 10.

At least one of components of the electronic device 10 as described above may be included in the display device according to the above-described embodiments. Additionally, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

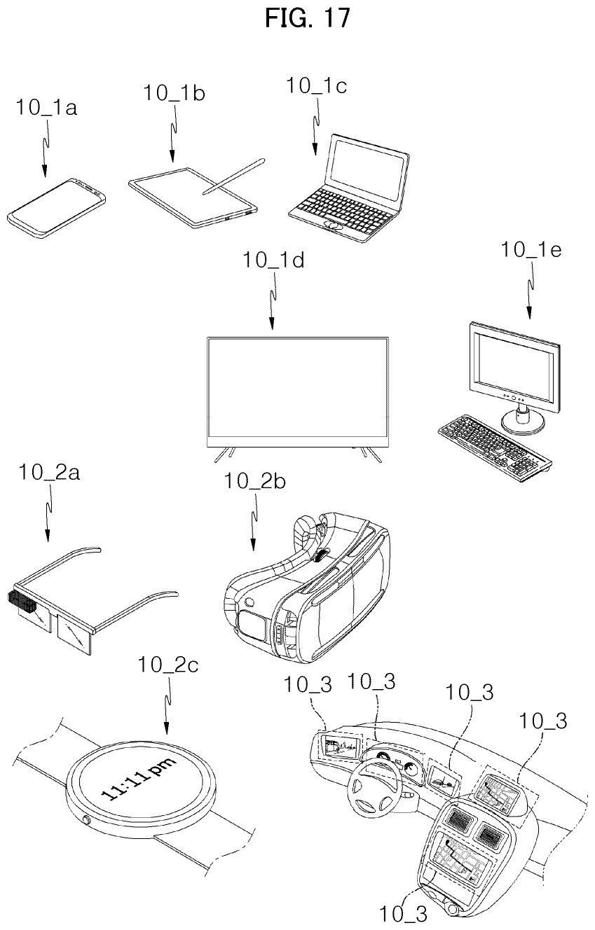

FIG. 17 is a schematic diagram of an electronic device in accordance with various embodiments.

Referring to FIG. 17, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, and the like; a wearable electronic device including a display module such as smart glasses 10_2a, a head mounted display 10_2b, a smart watch 10_2c, and the like; a vehicle electronic device 10_3 including a display module such as a center information display (CID) disposed at a vehicle instrument panel, a center fascia, a dashboard, etc., a room mirror display, and the like. The electronic device may include a virtual reality glass or an augmented reality glass.

What is claimed is:

1. A display device, comprising:
a base substrate;
a first unit display area and a second unit display area, each of which is arranged on the base substrate and includes at least one pixel;
a partial capping layer selectively covering only the at least one pixel included in the first unit display area; and
a light-shielding layer on the second unit display area to separate the second unit display area from the first unit display area.

2. The display device according to claim 1, further comprising a common capping layer covering both the first unit display area and the second unit display area,
wherein the partial capping layer is disposed on the common capping layer.

3. The display device according to claim 2, wherein a refractive index of the partial capping layer and a refractive index of the common capping layer are different from each other.

4. The display device according to claim 2, wherein a top surface of the partial capping layer has a surface roughness greater than a surface roughness of a top surface of the common capping layer.

5. The display device according to claim 1, wherein each of the first unit display area and the second unit display area includes a first pixel, a second pixel and a third pixel corresponding to different colors.

6. The display device according to claim 5, wherein the partial capping layer commonly covers the first pixel, the second pixel and the third pixel included in the first unit display area.

7. The display device according to claim 5, wherein the light-shielding layer includes a first opening, a second opening and a third opening that are above the first pixel, the second pixel and the third pixel, respectively, included in the second unit display area.

8. The display device according to claim 7, wherein the first opening and the second opening have an area larger than an area of the first pixel and the second pixel, respectively.

9. The display device according to claim 8, wherein a first margin gap is defined between the first opening and the first pixel, and a second margin gap larger than the first margin gap is defined between the second opening and the second pixel.

10. The display device according to claim 5, wherein each of the first pixel, the second pixel and the third pixel of the second unit display area is divided into a plurality of sub-pixels.

11. The display device according to claim 1, wherein the partial capping layer includes a plurality of grains spaced apart from each other.

12. The display device according to claim 1, further comprising an encapsulation layer between the partial capping layer and the light-shielding layer,
wherein the encapsulation layer includes a first encapsulation layer, a second encapsulation layer and a third encapsulation layer sequentially stacked from the partial capping layer,
wherein a thickness of the partial capping layer is smaller than a thickness of the first encapsulation layer.

13. The display device according to claim 12, wherein each of the first encapsulation layer and the third encapsulation layer includes an inorganic insulating material, and the second encapsulation layer includes an organic material.

14. The display device according to claim 1, wherein the partial capping layer partially overlaps the light-shielding layer.

15. The display device according to claim 1, wherein the first unit display area is selectively driven only in a normal mode, and the second unit display area is commonly driven in the normal mode and a private mode.

16. A display device, comprising:
a base substrate;
a first pixel group and a second pixel group arranged on the base substrate, wherein the first pixel group is selectively driven only in a normal mode, and the second pixel group is commonly driven in the normal mode and a private mode; and
a light-scattering layer selectively covering only the first pixel group.

17. The display device according to claim 16, further comprising a common capping layer covering both the first pixel group and the second pixel group,
wherein the light-scattering layer is disposed on the common capping layer.

18. The display device according to claim 17, further comprising:
an encapsulation layer covering the common capping layer and the light-scattering layer; and
a light-shielding layer on the encapsulation layer,
wherein the light-shielding layer has an opening that corresponds to a pixel included in the second pixel group, and does not overlap the first pixel group.

19. The display device according to claim 16, wherein a pixel area included in the second pixel group is smaller than a pixel area included in the first pixel group.

20. An electronic device, comprising:
a display device;
a memory; and
a processor for executing data included in the memory to control an operation of the display device,
wherein the display device comprises:
a base substrate;
a first unit display area and a second unit display area, each of which is arranged on the base substrate and includes at least one pixel;
a partial capping layer selectively covering only the at least one pixel included in the first unit display area; and
a light-shielding layer on the second unit display area to separate the second unit display area from the first unit display area.
